(19) United States
(12) Patent Application Publication
(10) Pub. No.: US 2020/0042500 A1
(43) Pub. Date: Feb. 6, 2020

(54) COLLABORATIVE COMPRESSION IN A DISTRIBUTED STORAGE SYSTEM

(71) Applicant: Alibaba Group Holding Limited, George Town (KY)

(72) Inventors: Shu Li, Bothell, WA (US); Ping Zhou, Folsom, CA (US)

(73) Assignee: Alibaba Group Holding Limited, George Town (KY)

(21) Appl. No.: 16/365,429

(22) Filed: Mar. 26, 2019

Related U.S. Application Data
(60) Provisional application No. 62/713,906, filed on Aug. 2, 2018.

(51) Int. Cl. G06F 16/174; H03M 7/30; H04L 29/08; G06F 3/06

(52) U.S. Cl. CPC G06F 16/1744; H03M 7/3073; H03M 7/6041; G06F 3/067; H04L 67/1097

(57) ABSTRACT

Embodiments described herein provide a system comprising a storage unit, a control module, a compression module, and a communication module. During operation, the storage unit can store a piece of data. The control module determines whether data stored in the storage unit has triggered a storage operation in a distributed storage system. The compression module then compresses the piece of data by encoding the piece of data using fewer bits than the bits of the piece of data. Subsequently, the communication module sends the compressed piece of data to a plurality of storage nodes in the distributed storage system for persistent storage.

### RELATED APPLICATION

This application claims the benefit of U.S. Provisional Application No. 62/713,906, Attorney Docket No. ALI-A15933USP, titled “Compression Collaboration with Distributed System for Efficiency and Performance Enhancement,” by inventor Shu Li, filed 2 Aug. 2018, the disclosure of which is incorporated herein by reference in its entirety.

### BACKGROUND

### Field

This disclosure is generally related to the field of storage management. More specifically, this disclosure is related to a system and method for facilitating compression collaboration among client and storage nodes in a distributed storage system.

### Related Art

A variety of applications running on physical and virtual devices have brought with them an increasing demand for computing resources. As a result, equipment vendors race to build larger and faster computing equipment (e.g., processors, storage, memory devices, etc.) with versatile capabilities. However, the capability of a piece of computing equipment cannot grow infinitely. It is limited by physical space, power consumption, and design complexity, to name a few factors. Furthermore, computing devices with higher capability are usually more complex and expensive. More importantly, because an overly large and complex system often does not provide economy of scale, simply increasing the size and capability of a computing device to accommodate higher computing demand may prove economically unviable.

With the increasing demand for computing, the demand for high-capacity storage devices is also increasing. Such a storage device typically needs a storage technology that can provide large storage capacity as well as efficient storage/retrieval of data. One such storage technology can be based on Not AND (NAND) flash memory devices (or flash devices). NAND flash devices can provide high capacity storage at a low cost. As a result, NAND flash devices have become the primary competitor of traditional hard disk drives (HDDs) as a persistent storage solution. To increase the efficiency of a NAND flash device, data received for storage is typically compressed prior to storing in the storage cells. This compression process can compress the data by encoding the data using fewer bits than the received bits.

Even though data compression has brought many desirable features of efficient data storage to NAND flash devices, many problems remain unsolved in efficient data compression in a distributed storage system.

### SUMMARY

Embodiments described herein provide a system comprising a storage unit, a control module, a compression module, and a communication module. During operation, the storage unit can store a piece of data. The control module determines whether data stored in the storage unit has triggered a storage operation in a distributed storage system. The compression module then compresses the piece of data by encoding the piece of data using fewer bits than the bits of the piece of data. Subsequently, the communication module sends the compressed piece of data to a plurality of storage nodes in the distributed storage system for persistent storage.

In a variation on this embodiment, the storage operation is triggered in response to one of: data stored in the storage unit reaching a threshold, and a timer expiring for the storage unit.

In a variation on this embodiment, the control module can query for a storage path for the compressed piece of data from a master node of the distributed storage service. The storage path can indicate the plurality of storage nodes.

In a further variation, the control module queries the master node for a location of the compressed piece of data based on metadata associated with the piece of data and determines a storage node from the plurality of storage nodes based on a query response from the master node. The communication module then sends a read request to the storage node for the compressed piece of data.

In a further variation, the communication module receives the piece of data with original bits from the storage node.

In a variation on this embodiment, the system can also include an interface module that performs a storage read operation on the piece of data. The storage read operation is executed for reading data from the storage unit and transferring data to one or more storage nodes for persistent storage.

In a variation on this embodiment, the system can also include an organization module that applies a set of organization operations on the piece of data that excludes operations of the compression circuitry prior to storing the piece of data in the storage unit. The set of organization operations includes one or more of: encryption, data validation, error-correction code (ECC) encoding, and data scrambling.

Embodiments described herein provide a system comprising a non-volatile storage unit, an interface module, a control module, a decompression module, and a communication module. During operation, the storage unit can store a compressed piece of data. The interface module identifies a request for the compressed piece of data from a client node of a distributed storage system. The control module determines that the request for the compressed piece of data triggers a user read operation. The decompression module then decompresses the compressed piece of data to generate a piece of data. The compressed piece of data includes fewer bits than the bits of the piece of data. Subsequently, the communication module sends the piece of data to the client node.

In a variation on this embodiment, the communication module receives a message comprising compressed piece of data. The control module then determines that the compressed piece of data has already been compressed.

In a further variation, the system includes an organization module that applies a set of organization operations on the compressed piece of data that excludes operations of a compression module of the system. The set of organization operations includes one or more of: encryption, data validation, error-correction code (ECC) encoding, and data scrambling.

In a variation on this embodiment, the control module determines that a background read has been initiated for the compressed piece of data, obtains the compressed piece of data from the storage unit, and bypasses the operations of the decompression circuitry for the compressed piece of data.

In a further variation, the control module performs an operation associated with the background read in conjunction with a plurality of storage nodes of the distributed storage system. A respective storage node of the plurality of storage nodes can store a copy of the compressed piece of data.

In a further variation, the control module queries a master node of the distributed storage system to determine the plurality of storage nodes.

In a variation on this embodiment, the storage unit comprises a plurality of non-volatile memory cells facilitating persistent storage.

Embodiments described herein provide a system. During operation, the system receives a first piece of metadata associated with a piece of data from a client node of a distributed storage system. The system can also receive a second piece of metadata associated with a compressed piece of data from the client node. The compressed piece of data can be generated by compressing the piece of data and includes fewer bits than the bits of the piece of data. The system then registers the first piece of metadata for the distributed storage system and generates a mapping between the first and second pieces of metadata.

In a further variation, the system generates a storage path indicating a plurality of storage nodes of the distributed storage system for the compressed piece of data and sends the storage path to the client node.

In a variation on this embodiment, the system stores the storage path in association with the second piece of metadata.

In a further variation, the system receives a query for information based on the first piece of metadata, looks up in the mapping to obtain the second piece of metadata, and retrieves the storage path based on the second piece of metadata.

In a further variation, the system selects a storage node from the plurality of storage nodes for retrieving the piece of data and sends, to the client node, a notification indicating the selected storage node.

In a variation on this embodiment, the system can send an instruction message to a storage node indicating a location for storing the compressed piece of data.

### BRIEF DESCRIPTION OF THE FIGURES

FIG. 1A illustrates an exemplary infrastructure facilitating collaborative compression in a distributed storage system, in accordance with an embodiment of the present application.

FIG. 1B illustrates exemplary device configurations for facilitating collaborative compression in a distributed storage system, in accordance with an embodiment of the present application.

FIG. 2 illustrates exemplary read and write paths for facilitating collaborative compression in a distributed storage system, in accordance with an embodiment of the present application.

FIG. 3 illustrates an exemplary collaborative compression and corresponding data retrieval in a distributed storage system, in accordance with an embodiment of the present application.

FIG. 4A illustrates exemplary read and write paths of the controller of a client cache of a client node, in accordance with an embodiment of the present application.

FIG. 4B illustrates exemplary read and write paths of the controller of a storage device of a storage node, in accordance with an embodiment of the present application.

FIG. 5A presents a flowchart illustrating a method of a client node compressing data for storing in a storage node in a distributed storage system, in accordance with an embodiment of the present application.

FIG. 5B presents a flowchart illustrating a method of one or more master nodes maintaining information associated with collaborative compression in a distributed storage system, in accordance with an embodiment of the present application.

FIG. 5C presents a flowchart illustrating a method of a storage node storing data without local compression in a distributed storage system, in accordance with an embodiment of the present application.

FIG. 6A presents a flowchart illustrating a method of a client node retrieving data from a storage node in a distributed storage system, in accordance with an embodiment of the present application.

FIG. 6B presents a flowchart illustrating a method of a storage node retrieving data for a client node in a distributed storage system, in accordance with an embodiment of the present application.

FIG. 6C presents a flowchart illustrating a method of a storage node retrieving data for a background read in a distributed storage system, in accordance with an embodiment of the present application.

FIG. 7 illustrates an exemplary computer system that facilitates collaborative compression in a distributed storage system, in accordance with an embodiment of the present application.

FIG. 8 illustrates an exemplary apparatus that facilitates collaborative compression in a distributed storage system, in accordance with an embodiment of the present application.

In the figures, like reference numerals refer to the same figure elements.

### DETAILED DESCRIPTION

The following description is presented to enable any person skilled in the art to make and use the embodiments, and is provided in the context of a particular application and its requirements. Various modifications to the disclosed embodiments will be readily apparent to those skilled in the art, and the general principles defined herein may be applied to other embodiments and applications without departing from the spirit and scope of the present disclosure. Thus, the embodiments described herein are not limited to the embodiments shown, but are to be accorded the widest scope consistent with the principles and features disclosed herein.

### Overview

The embodiments described herein solve the problem of efficiently compressing data in a distributed storage system by (i) offloading compression operations to the client nodes and bypassing the compression operations at the storage nodes during data storage; and (ii) decompressing the data at the storage node, if needed, when data is retrieved from the local storage device.

Typically, the architecture of the system includes a number of client nodes, storage nodes, and master nodes. The client nodes receive the client data and corresponding requests. On the other hand, the storage nodes store the data. To facilitate high availability and high reliability, each piece of data can be stored in multiple storage nodes and/or storage devices. Master nodes can store and organize the metadata associated with the storage operations and the data stored. The term “storage device” can refer to a device with non-volatile memory configured to store data through a power cycle (e.g., if the host device of the storage device is turned off and, subsequently, on again). For a client node, which can also be referred to as a compute node, the storage device can be any non-volatile media. On the other hand, for a storage node, the storage device can be a solid-state disk (SSD) comprising a number of storage cells. For example, a single-level cell (SLC) of the SSD can store one bit, while a quad-level cell (QLC) can store four bits.

With existing technologies, data compression may not incorporate the data storage architecture of a distributed storage system (e.g., a datacenter). For example, data is typically stored in the storage nodes with redundancy to facilitate high availability. However, that data typically originates at the client nodes (or compute nodes). As a result, compressing data at the storage nodes repeats the compression process for a respective storage device that may store the data. In addition, the uncompressed data is typically transferred from the client nodes to the storage nodes over a network. Consequently, that network may carry a large quantity of data. Furthermore, the extensive resource consumption within a device for the data transfer can lead to performance bottleneck (e.g., memory or data bus can become saturated).

Since the compression efficiency of a CPU can be inefficient, a storage node can be equipped with a dedicated piece of hardware that performs the compression operation (e.g., a field-programmable gate array (FPGA)-based compression card). However, since the piece of hardware shares the internal bus (e.g., the peripheral component interconnect express (PCIe) bus) with the storage device, the performance can still remain inefficient. Therefore, a dedicated piece of hardware may still retain a number of inefficiencies associated with data compression due to its “single node” design that does not consider the way data is stored in a distributed storage system.

For example, since the processors of the storage node can be relatively simpler, the compression operation on the processors can incur high latency. On the other hand, using a dedicated piece of hardware may not be cost-effective and can increase the power consumption. The data compressed using the piece of hardware may still have to go back to the local processors, and proceed through the storage stack. As a result, such a configuration can cause bottleneck and delay in the internal bus of the storage device.

To solve these problems, embodiments described herein provide a collaborative compression technique that allows both client and storage nodes to participate in the compression process. The compression operations can be offloaded to the client nodes, while the decompression operations can be performed by the storage nodes. To facilitate data compression, a respective client node can be equipped with a persistent client cache (e.g., based on non-volatile memory) that can asynchronously store received and/or locally generated data. Since the client node can store the data without compression, the client cache can quickly store the data. The client cache can store the uncompressed data for a limited period of time and transfer the data to the storage nodes for longer-term storage with high availability.

To do so, the client node reads the data from the client cache and performs the compression operation. In this way, the data compression operation can be integrated in the “read path” of the client node instead of a “write path” of a storage node. The write/read paths can include a number of organization operations, such as compression/decompression, encryption/decryption, data validation (e.g., cyclic-redundancy check (CRC)), error-correction code (ECC) encoding/decoding, and scrambling/descrambling, executed by corresponding modules. The compression operation can be executed in the background while storing other user data in the client cache. As a result, the compression operation may not affect the user experience. In some embodiments, the compression operation can be executed by a hardware module of the controller of the client cache (e.g., an SSD controller). Such a hardware-based execution can be implemented using circuitry available in the controller.

The master nodes can store the metadata associated with the data, such as a mapping between the respective metadata of compressed and uncompressed data, and the storage path for the compressed data indicating which storage nodes should store the compressed data. This mapping allows a client node to determine the location of the compressed data based on a user request of the uncompressed data. In other words, when the client node receives a user request for the data, the client node can look up the corresponding metadata associated with the compressed data. The client node can also obtain the corresponding storage path of the compressed data.

The compressed data is then transferred via the network to the storage nodes selected by the master nodes. Upon receiving the compressed data, a storage node can store the data bypassing any compression operation on the data. As a result, the compression operation is not repeated at each of the storage nodes that store the data. To retrieve the data, a client node obtains the location information of the data. In some embodiments, the master nodes can select one of the storage nodes storing the compressed data based on a selection policy, which can be based on one or more of: a round robin selection, the network load, and the device load of a respective storage node. The client node can request the compressed data from the selected storage node.

The storage node then reads the compressed data from a local storage device, decompresses the data, and provides the uncompressed data to the client device via the network. In this way, the data decompression operation can be integrated in the “read path” of the storage node while the corresponding data compression operation can be integrated in the “read path” of the client node. In some embodiments, the decompression operation is not triggered during a background read from the storage node. A read operation not initiated by a user and/or a client node can be referred to as a background read operation. For example, the system can retrieve the data from different storage nodes to check the validity of the data. Such validation can be performed using the compressed data. As a result, for a background read operation of the system, the decompression may not be used, thereby further improving the efficiency of the system.

### Exemplary System

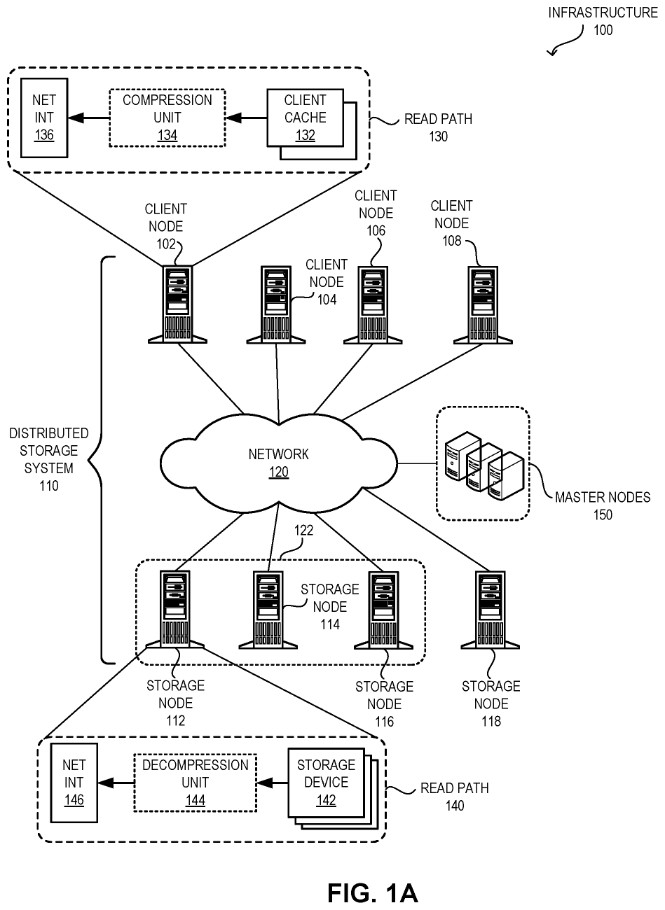

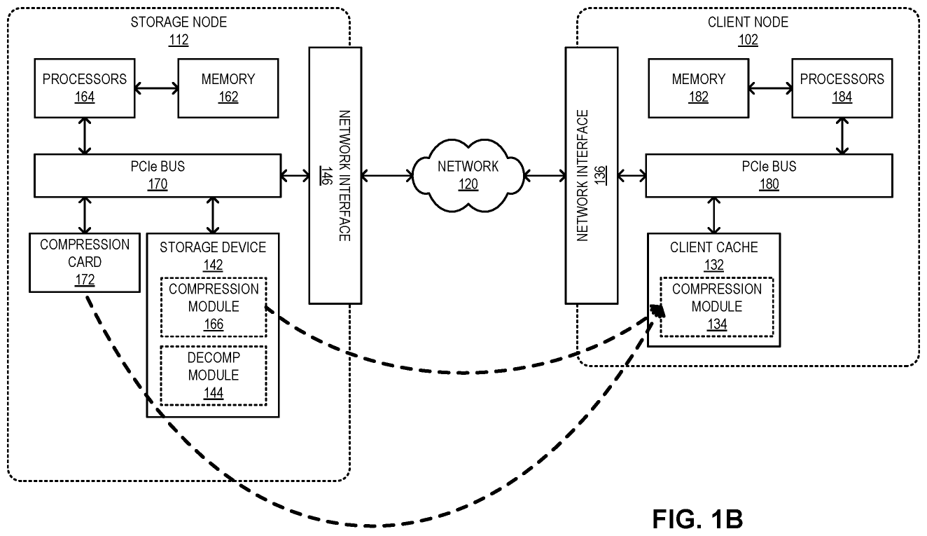

FIG. 1A illustrates an exemplary infrastructure facilitating collaborative compression in a distributed storage system, in accordance with an embodiment of the present application. In this example, an infrastructure 100 can include a distributed storage system 110. System 110 can include a number of client nodes (or client-serving machines) 102, 104, 106, and 108, and a number of storage nodes 112, 114, 116, and 118. Client nodes 102, 104, 106, and 108, and storage nodes 112, 114, 116, and 118 can communicate with each other via a network 120 (e.g., a local or a wide area network, such as the Internet). A storage node can also include one or more storage devices. For example, storage node 112 can include components such as a number of central processing unit (CPU) cores, a system memory device, a network interface card (NIC), and at least one storage device/disk 142. Storage device 142 can be a high-density non-volatile memory device, such as a NAND-based SSD.

With existing technologies, data compression may not incorporate the data storage architecture of system 110. For example, data is typically stored in a plurality of storage nodes of system 110 to facilitate high availability based on redundancy. However, that data typically originates at one of the client nodes of system 110. As a result, compressing data at the plurality of storage nodes of system 110 repeats the compression process. In addition, since the uncompressed data can include a larger number of bits, network 120 may carry a large quantity of data from the client nodes. Furthermore, the extensive resource consumption within a storage node of system 110 for storing and retrieving the data can lead to performance bottleneck within a storage node (e.g., memory or data bus can become saturated).

To solve these problems, system 110 can facilitate a collaborative compression technique that allows both client and storage nodes to participate in the compression process. Suppose that data is transferred from client node 102 to a plurality of storage nodes in system 110. The compression operations can then be offloaded to client node 102 while the decompression operations can be performed by the plurality of storage nodes. To facilitate data compression, client node 102 can be equipped with a persistent client cache 132 (e.g., based on non-volatile memory) that can asynchronously store received and/or locally generated data. Since client node 102 can store the data without compression, client cache 132 can quickly store the data. Client cache 132 can store the uncompressed data for a limited period of time and transfer the data to the plurality of storage nodes for longer-term storage with high availability. For example, if data stored in client cache 132 reaches a threshold (e.g., a data storage block) or a timer has expired for client cache 132, client node 102 can initiate the data transfer.

To transfer the data, client node 102 reads the data from client cache 132 and performs the compression operation. In this way, the data compression operation can be integrated in read path 130 of client node 102. In some embodiments, the compression operation can be executed by a compression unit 134 of client cache 132. Such a hardware-based execution can be implemented using circuitry available in client cache 132. Compression unit 134 can perform the compression operation in the background while client node 102 stores other user data in client cache 132. As a result, the compression operation may not affect the user experience of client node 102.

System 110 can also include one or more master nodes 150 that can store the metadata associated with the data, such as a mapping between the respective metadata of compressed and uncompressed data, and the storage path for the compressed data indicating which storage nodes, such as storage node 112, should store the compressed data. When master nodes 150 store the metadata, client 102 transfers the compressed data via a local network interface (e.g., a network interface card (NIC)) 136 through network 120 to a set of storage nodes 122 selected by master nodes 150. Storage nodes 122 facilitate redundancy of the data and can include storage nodes 112, 114, and 116. Upon receiving the compressed data, a storage node of storage nodes 122 can store the compressed data. For example, storage node 112 can store the compressed data bypassing any compression operation on the data. As a result, the compression operation is not repeated at each of storage nodes 122.

Client node 102 can retrieve the data by obtaining the metadata (e.g., the location information) of the data from master nodes 150. The metadata can include the mapping that allows client node 102 to determine the location of the compressed data based on a user request of the uncompressed data. In other words, when client node 102 receives a user request for the data, client node 102 can look up the corresponding metadata associated with the compressed data from master nodes 150. Client node 102 can also obtain the corresponding storage path of the compressed data. In some embodiments, master nodes 150 can select one of storage nodes 122 based on a selection policy, which can be based on one or more of: a round robin selection, the network load, and the device load of a respective storage node of storage nodes 122. Suppose that master nodes 150 selects storage node 112. Client node 102 can then request the compressed data from storage node 112.

Storage node 112 then reads the compressed data from local storage device 142, decompresses the data to obtain the original data, and provides the data to client device 102 via network interface 146 through network 120. In this way, the data decompression operation can be integrated in read path 140 of storage node 112. In some embodiments, the decompression operation can be executed by a decompression unit 144 of storage device 142. For example, decompression unit 144 can be integrated with the controller of storage device 142. In some embodiments, decompression unit 144 does not trigger its operations during a background read from storage node 112. As a result, for a background read operation of system 110, decompression unit 144 may not be used, thereby further improving the efficiency of the data processing of system 110.

FIG. 1B illustrates exemplary device configurations for facilitating collaborative compression in a distributed storage system, in accordance with an embodiment of the present application. Storage node 112 can include a volatile memory 162 (e.g., a dual in-line memory module (DIMM)), and one or more processors 164 (e.g., a multi-core processor). Processors 164 can be coupled to storage device 142 via a PCIe bus 170. Similarly, client node 102 can include a volatile memory 182 and one or more processors 184. Processors 184 can be coupled to client cache 132 via a PCIe bus 180. Without the collaborative compression, storage node 112 may perform compression operations on data received from client node 102 using processors 164.

However, since the compression efficiency of processors 164 can be inefficient, storage node 112 can be equipped with a compression card 172, which can be a dedicated piece of hardware, such as an FPGA-based card, that performs the compression operation. Since compression card 172 uses PCIe bus 170 for internal communication with storage device 112, compressed data is transferred from compression card 172 via PCIe bus 170 to processors 164, which in turn, can use PCIe bus 170 to store data in storage device 142. This long operational path within storage node 112 can lead to high latency and PCIe bus 170 can become a performance bottleneck.

To resolve this issue, storage device 142 can be equipped with a compression module 166 that can facilitate the operations of compression card 172. This can reduce the internal latency within storage device 112. However, the processing capability of compression module 166 can be relatively limited. On the other hand, using compression card 172 may not be cost-effective and can increase the power consumption of storage node 112. To resolve these issues, the collaborative compression technique can shift the operations of compression card 172 and/or compression module 166 to compression module 134 of client node 102. Compression module 134 can be integrated with the controller of client cache 132. When client node 102 reads data from client cache 132 for storing in storage node 112, compression module 134 can compress the data. Client node 102 can then send the compressed data using network interface 136 to storage node 112.

### Exemplary Architecture and Data Flow

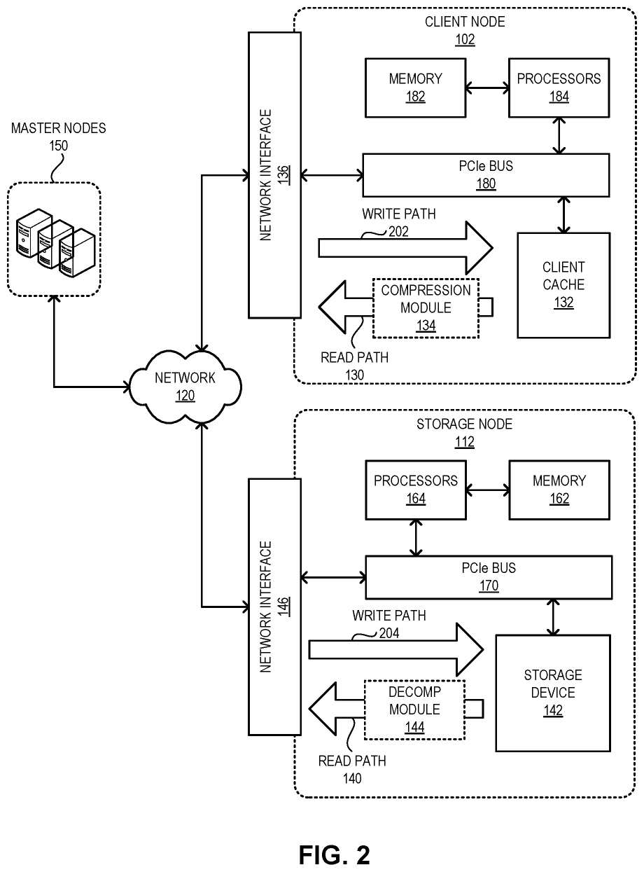

FIG. 2 illustrates exemplary read and write paths for facilitating collaborative compression in a distributed storage system, in accordance with an embodiment of the present application. During operation, upon receiving user data, instead of directly sending the data to storage node 112 for storage, client node 102 can asynchronously store the data in client cache 132 through a write path 202. Even if compression module 134 can compress data in write path 202, client node 102 can bypass the compression operation in write path 202 and store the data in client cache 132. Since the write operations are asynchronous and the compression operation is bypassed, client node 102 can execute the write operation via write path 202 with lower latency. When the data in client cache 132 reaches a threshold or a timer has expired, client node 102 reads the data from client cache 132 and performs the compression operation using compression module 134 on read path 130.

Since the compression operation is placed on read path 130 of client cache 132, the compression operation can be executed as a background operation that does not affect the user operations at client node 102. In addition, to lessen the computational burden on processors 184 and load on memory 182, compression module 134 can be a hardware module on a controller of client cache 132. The hardware module can be based on logic circuitry and may be integrated in some flash storage device controllers. If client cache 132 is equipped with compression module 134, it can also mitigate the write amplifications of client cache 132. Client node 102 can then send the compressed data to storage node 112 via network interface 136 through network 120.

Storage node 112 receives the compressed data via network interface 146 and stores the compressed data in storage device 142 through a write path 204. Even though storage device 142 can include a compression module in write path 204, storage node 112 can bypass the compression module and store the compressed data in storage device 142. If client node 102 requests the data, storage node 112 can obtain the compressed data from storage device 142 though read path 140. Storage node 112 can use decompression module 144 operating on read path 140 to decompress the obtained data and generate the original decompressed data. Storage node 112 can then send the uncompressed data to client node 102 via network interface 146 through network 120.

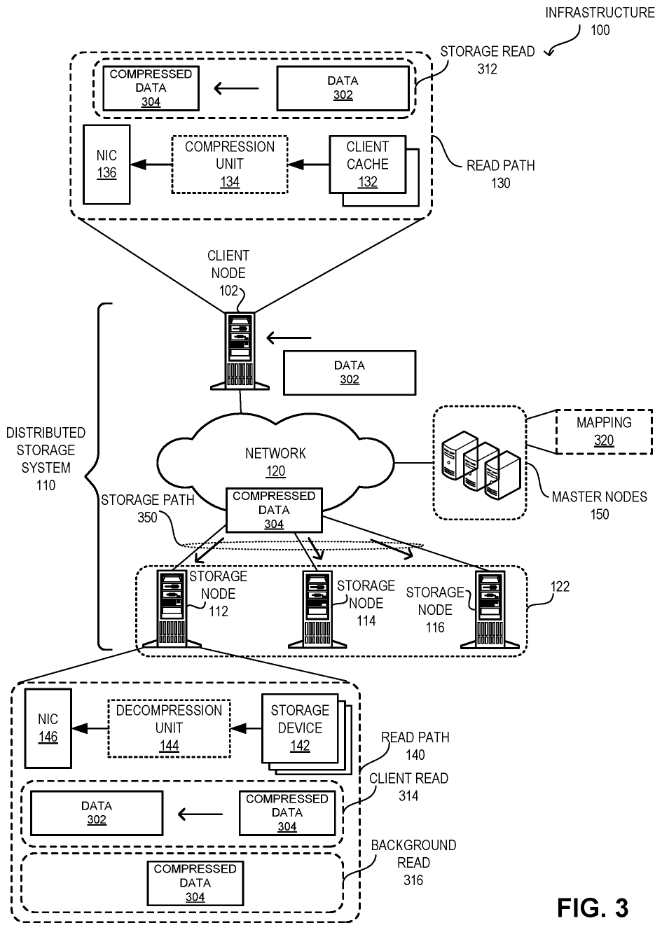

FIG. 3 illustrates an exemplary collaborative compression and corresponding data retrieval in a distributed storage system, in accordance with an embodiment of the present application. Infrastructure 100 can provide a collaborative compression technique that allows client node 102 and storage node 112 to participate in the compression and corresponding decompression process. In other words, the collaborative compression indicates both the compression and the decompression operation executed in collaboration among client and storage nodes. During operation, upon receiving data 302 from a user, client node 102 asynchronously stores data 302 in client cache 132. Client cache 132 can store data 302 for a limited period of time and transfer data 302 to storage nodes 122 for longer-term storage with high availability.

To do so, client node 102 can execute a storage read operation 312 that reads data from client cache 132 for storing in storage nodes 122. Read operation 312 can follow read path 130 and include the compression operation executed by compression unit 134 to generate compressed data 304. In this way, the data compression operation can be integrated in read path 130 of client node 102 instead of write paths of storage nodes 122. Read path 130 can include a number of organization operations, such as decompression, decryption, data validation using CRC, ECC decoding, and descrambling. Since the collaborative compression operation is distributed across client node 102 and storage nodes 122, master nodes 150 can store the metadata associated with data 302 to ensure accessibility to both client node 102 and storage nodes 122. The metadata can include a mapping 320 between the respective metadata of data 302 and compressed data 304, and the storage path for compressed data 304 indicating that storage nodes 122 should store compressed data 304.

Client node 102 then transfers compressed data 304 via network 120 to storage nodes 122, which are selected by master nodes 150. Upon receiving compressed data 304, a respective storage node of storage nodes 122 can store compressed data 304, bypassing any compression operation on compressed data 304. As a result, the compression operation is only executed once on client node 102 and not repeated at each of storage nodes 122. To retrieve the data, client node 102 obtains the location information of compressed data 304. Mapping 320 allows client node 102 to determine the location of compressed data 304 based on a user request of data 302.

In other words, when client node 102 receives a user request for data 302, client node 102 can look up the metadata associated with compressed data 304 using metadata of data 302. Client node 102 can also obtain the corresponding storage path of compressed data 304. In some embodiments, master nodes 150 can select one of storage nodes 122 for client node 102 to retrieve compressed data 304 based on a selection policy. Suppose that master nodes 150 selects storage node 112 from storage nodes 122 based on the selection policy, which can be based on one or more of: a round robin selection, the network load, and the device load of a respective storage node of storage nodes 122. Client node 102 can then request compressed data 304 from selected storage node 112.

Upon receiving the request from client node 102, storage node 112 can execute a client read operation 314 that reads data from storage device 142 for retrieving data in response to a client read request. Read operation 314 can follow read path 140 and include the decompression operation executed by decompression unit 144 to generate original data 302. In this way, the data decompression operation can be integrated in read path 140 of storage node 112. Read path 140 can include a number of operations, such as decompression, decryption, data validation using CRC, and ECC decoding. Storage node 112 then provides data 302 to client device 102 via network 120.

In some embodiments, the decompression operation is not triggered during a background read 316 in storage node 112. Background read operation 316 can be a read operation that is not initiated by a user and/or a client node 102. For example, system 110 can retrieve data 304 from multiple nodes of storage nodes 122 to check the validity of data 304. Such validation can be performed using compressed data 304 without decompressing. As a result, for background read operation 316, the operation of decompression unit 144 can be bypassed. This further reduces the number of operations on compressed data 304, thereby further improving the efficiency of system 110.

### Controller Paths

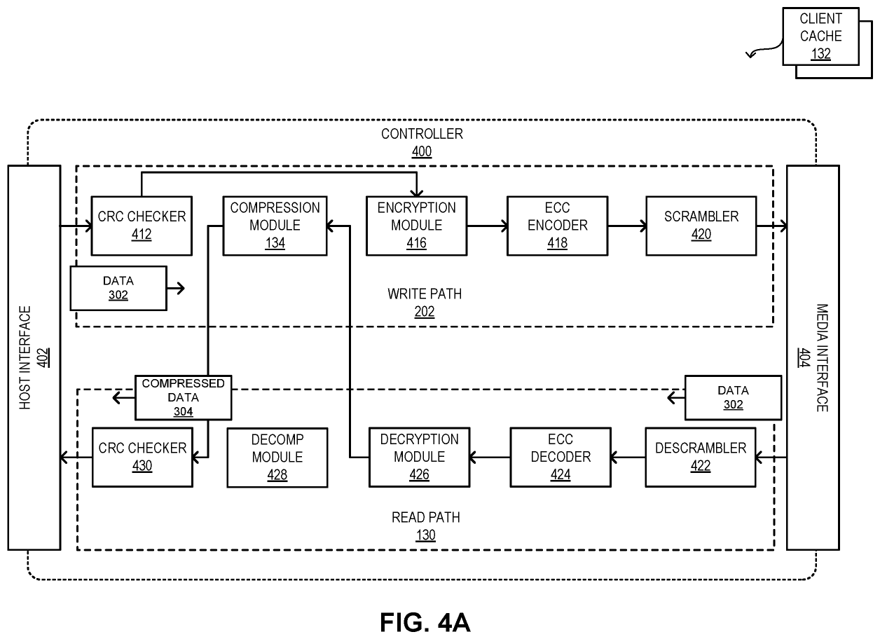

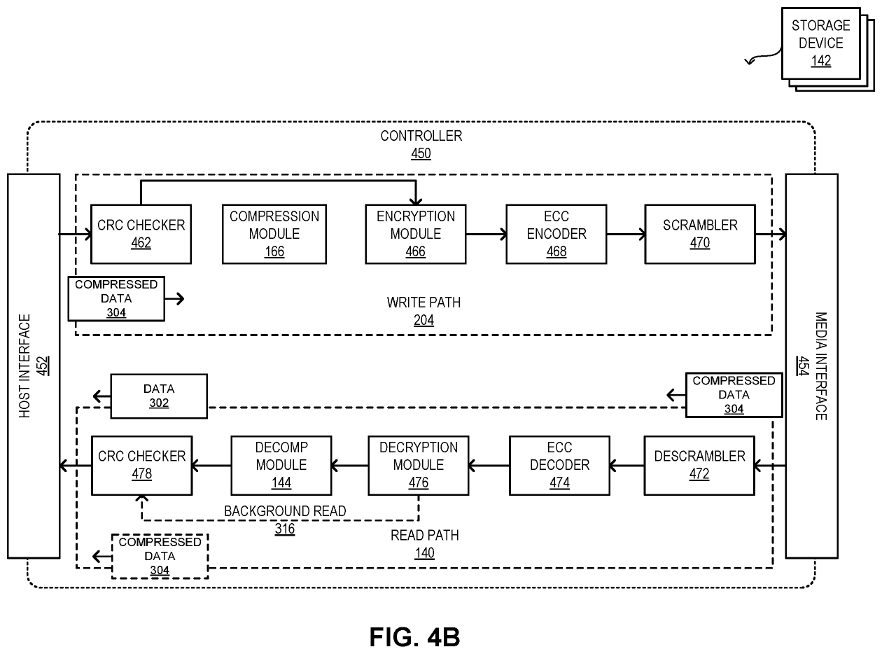

FIG. 4A illustrates exemplary read and write paths of the controller of a client cache of a client node, in accordance with an embodiment of the present application. Controller 400 of client cache 132 can include a host interface 402 for communicating with the host device (i.e., client node 102) and obtaining user data, and a media interface 404 for storing the data in client cache 132. During the execution of write path 202, controller 400 receives data 302 via host interface 402 and performs a CRC-based data validation using a CRC checker 412. This allows controller 400 to detect any error in data 302. To efficiently execute write path 202, controller 400 can bypass the operations of compression module 134 in write path 202 and uses encryption module 416 to encrypt data 302. The encryption operation can be based on an on-chip encryption mechanism, such as a self-encrypting mechanism for flash memory.

Subsequently, an ECC encoder 418 encodes data 302 with ECC to detect and/or correct bit error(s). Data scrambler 420 then scrambles the data signal (e.g., in the analog domain) of data 302 to obfuscate the signal. Controller 400 then programs data 302 in client cache 132 via media interface 404. In this way, data 302 can be stored in client cache 132 efficiently and asynchronously. Client cache 132 can temporarily store data 302. To transfer data to a storage node, controller 400 can retrieve data 302 via read path 130. During the execution of read path 130, controller 400 descrambles the data signal of data 302 using descrambler 422 and decodes data 302 using ECC decoder 424 with the ECC corresponding to that of encoder 418. A decryption module 426 then decrypts data 302.

Conventionally, a decompression module 428 decompresses data in read path 130. However, since controller 400 stores data 302 without compression, controller 400 can bypass the operations of decompression module 428. Instead, controller 400 incorporates the operations of compression module 134 into read path 130. Compression module 134 can compress data 302 to generate compressed data 304. Subsequently, CRC checker 430 can perform a CRC-based data validation and provide compressed data 304 via host interface 402. In this way, client cache 132 can facilitate temporary and asynchronous data storage, and generate compressed data 304 for collaborative compression. It should be noted that the modules of controller 400 can be based on software, hardware, or a combination thereof.

FIG. 4B illustrates exemplary read and write paths of the controller of a storage device of a storage node, in accordance with an embodiment of the present application. Controller 450 of storage device 142 can include a host interface 452 for communicating with the host device (i.e., storage node 112) and obtaining user data, and a media interface 454 for storing the data in storage device 142. During the execution of write path 204, controller 450 receives data compressed data 304 via host interface 452 and performs a CRC-based data validation using a CRC checker 462. This allows controller 450 to detect any error in compressed data 304. Conventionally, write path 204 can include compression module 166. However, since storage device 142 receives compressed data 304 for storage, controller 450 can bypass the operations of compression module 166.

Controller 400 then encrypts compressed data 304 using encryption module 466 and encodes compressed data 304 using ECC encoder 468. Subsequently, data scrambler 470 then scrambles the data signal of compressed data 304 to obfuscate the signal. Controller 450 then programs compressed data 304 in storage device 142 (e.g., in its storage cells) via media interface 454. In this way, compressed data 304 can be stored in storage device 142 without performing the compression operation in controller 450. To transfer data 302 back to client node 102, controller 450 can retrieve compressed data 304 via read path 140.

During the execution of read path 140, controller 450 descrambles the data signal of compressed data 304 using descrambler 472 and decodes compressed data 304 using ECC decoder 474 with the ECC corresponding to that of encoder 468. A decryption module 476 then decrypts compressed data 304. Controller 450 then decompresses compressed data 304 using decompression module 144 in read path 140 to obtain the original data 302. Decompression module 144 can deploy a decompression method corresponding to the compression method of compression module 134 of client cache 132. Subsequently, CRC checker 478 can perform a CRC-based data validation, and controller 450 can provide data 302 via host interface 452. In this way, storage device 142 can store compressed data 304 and perform the decompression operation to obtain data 302 for collaborative compression.

As described in conjunction with FIG. 3, controller 450 can bypass the operation of decompression module 144 in read path 140 for background read 316 in storage device 142. Compressed data 304 can be retrieved from multiple storage nodes to check the validity of compressed data 304. Such validation can be performed using compressed data 304 without decompressing. As a result, when decryption module 476 decrypts compressed data 304, controller 450 can use CRC checker 478 to perform the CRC-based data validation on compressed data 304. Controller 450 then can provide compressed data 304 via host interface 452 to facilitate the operations associated with background read 316. This can reduce the number of operations on compressed data 304, thereby further improving the efficiency of data retrieval in read path 140. It should be noted that the modules of controller 450 can be based on software, hardware, or a combination thereof.

### Operations

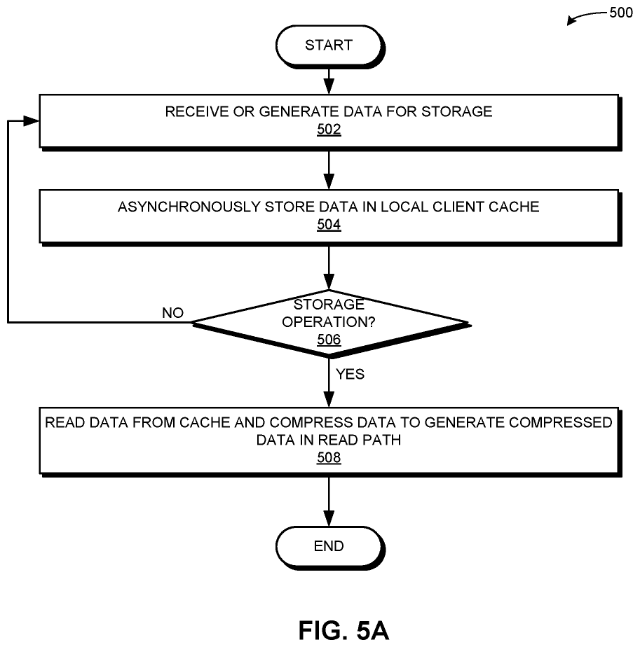

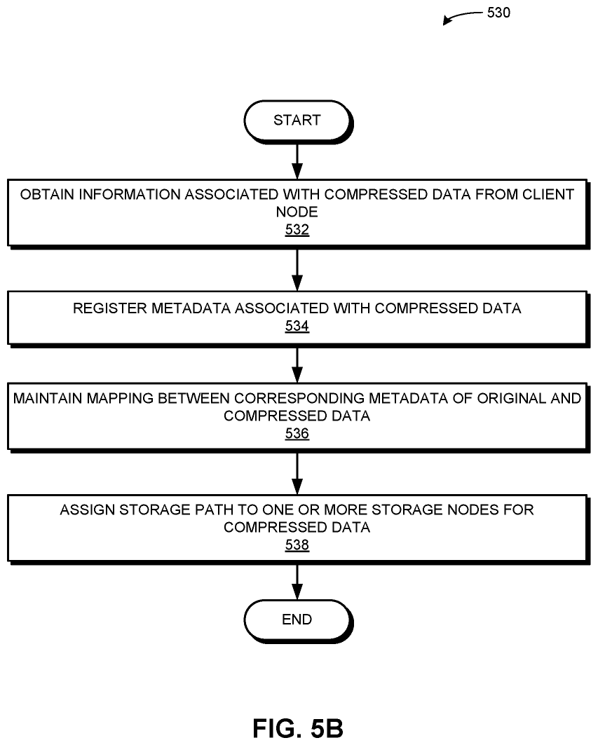

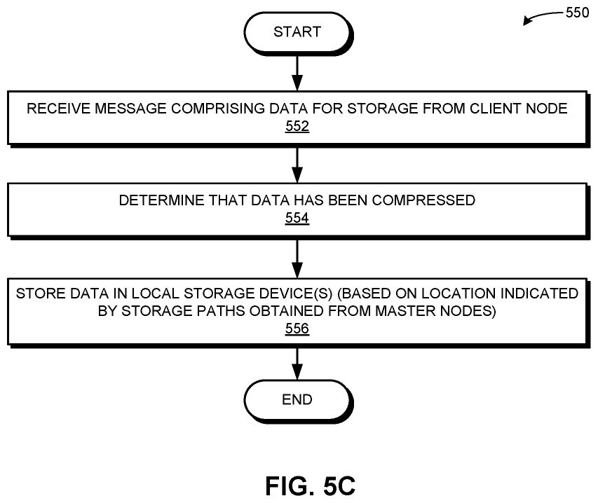

FIG. 5A presents a flowchart 500 illustrating a method of a client node compressing data for storing in a storage node in a distributed storage system, in accordance with an embodiment of the present application. During operation, the client node receives or generates data for storage (operation 502) and asynchronously stores the data in the local client cache (operation 504). The client node then checks whether a storage operation for the data is triggered (operation 506). For example, if the amount of data in the client cache reaches a threshold or a timer has expired for the client cache, the data storage operation can be triggered. If the storage operation is not triggered, the client node continues to receive or generate data for storage (operation 502). On the other hand, if the data operation is triggered, the client node reads data from the client cache and compresses the data to generate the compressed data in the read path (operation 508).

FIG. 5B presents a flowchart 530 illustrating a method of one or more master nodes maintaining information associated with collaborative compression in a distributed storage system, in accordance with an embodiment of the present application. During operation, the master nodes obtain information associated with the compressed data from the client node (operation 532) and register the metadata associated with the compressed data (operation 534). The master nodes also maintain a mapping between the corresponding metadata of the original and the compressed data (operation 536). The master nodes can assign a storage path to one or more storage nodes for the compressed data (operation 538). The assignment can include storing the information (e.g., location information and data path) associated with the storage path in association with the metadata associated with the data and/or the compressed data.

FIG. 5C presents a flowchart 550 illustrating a method of a storage node storing data without local compression in a distributed storage system, in accordance with an embodiment of the present application. During operation, the storage node receives a message comprising data from the client node (operation 552) and determines that the data has been compressed (operation 554). In some embodiments, the message can include information that indicates that the data is compressed and the type of compression used. The storage node can then store the data in one or more local storage devices (operation 556). The storage node can obtain the storage path for the data and store the data based on a location indicated by the storage path.

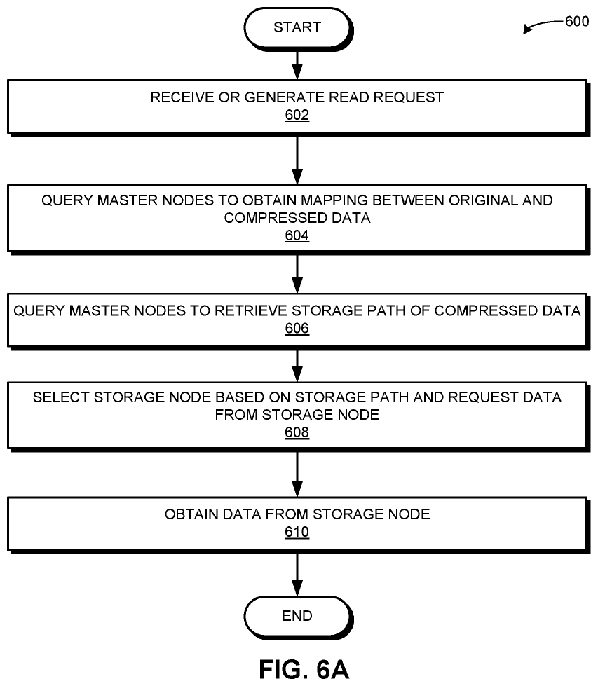

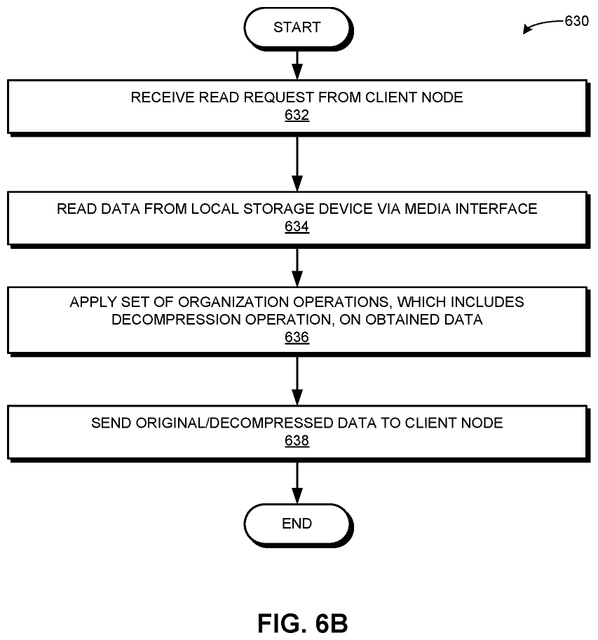

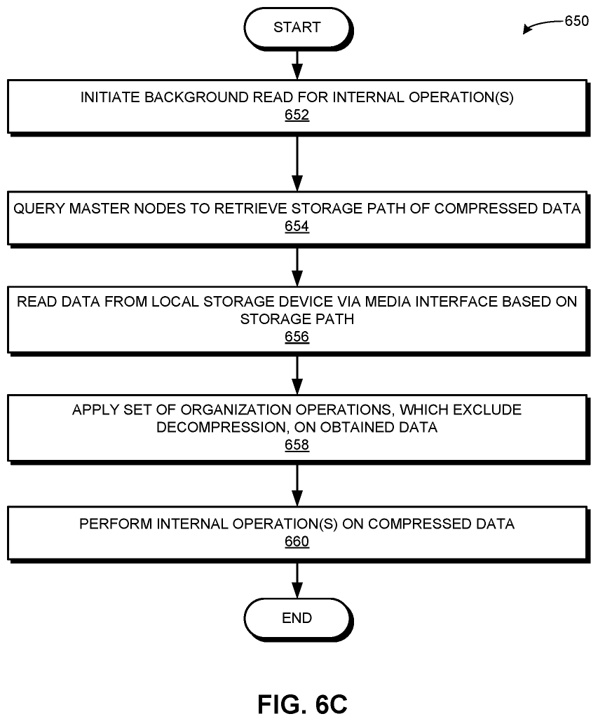

FIG. 6A presents a flowchart 600 illustrating a method of a client node retrieving data from a storage node in a distributed storage system, in accordance with an embodiment of the present application. During operation, the client node receives or generates a read request (operation 602), and queries the master nodes to obtain the mapping between the original and compressed data (operation 604). The client node can also query the master nodes to the storage path of the compressed data (operation 606). The client node selects a storage node based on the storage path and requests data from the storage node (operation 608), and obtains the data from the storage node (operation 610). Since the storage node performs the decompression operation, the client node can obtain the original data from the storage node.

FIG. 6B presents a flowchart 630 illustrating a method of a storage node retrieving data for a client node in a distributed storage system, in accordance with an embodiment of the present application. During operation, the storage node receives a read request from the client node (operation 632) and reads data from a local storage device via a media interface (operation 634). The storage node then applies a set of organization operations, which includes the decompression operation, on the obtained data (operation 636). In addition to the decompression operation, the set of organization operations can also include one or more of: decryption, data validation using CRC, ECC decoding, and data descrambling. The storage node then sends the original/decompressed data to the client node (operation 638).

FIG. 6C presents a flowchart 650 illustrating a method of a storage node retrieving data for a background read in a distributed storage system, in accordance with an embodiment of the present application. During operation, the storage node initiates a background read for internal operation(s) (operation 652) and queries the master nodes to retrieve the storage path of the compressed data (operation 654). The storage node then reads data from the local storage device via a media interface based on the storage path (operation 656) and applies a set of organization operations, which excludes the decompression operation, on the obtained data (operation 658). The storage node then performs the internal operation(s) on the compressed data (operation 660).

### Exemplary Computer System and Apparatus

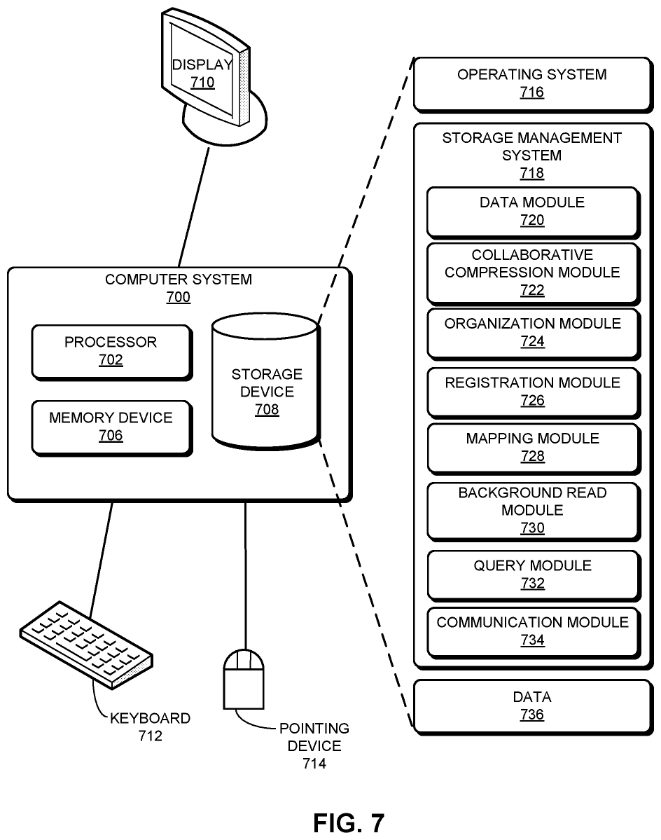

FIG. 7 illustrates an exemplary computer system that facilitates collaborative compression in a distributed storage system, in accordance with an embodiment of the present application. Computer system 700 includes a processor 702, a memory device 706, and a storage device 708. Memory device 706 can include a volatile memory (e.g., a dual in-line memory module (DIMM)). Furthermore, computer system 700 can be coupled to a display device 710, a keyboard 712, and a pointing device 714. Storage device 708 can store an operating system 716, a storage management system 718, and data 736. Storage management system 718 can facilitate the operations of one or more of: client node 102, storage node 112, one of master nodes 150, and controller 400/450. Storage device 708 can operate as one or more of: client cache 132 and storage device 142. Storage management system 718 can include circuitry to facilitate these operations.

Storage management system 718 can also include instructions, which when executed by computer system 700 can cause computer system 700 to perform methods and/or processes described in this disclosure. Specifically, storage management system 718 can include instructions for obtaining and/or generating data, providing the data to a client cache, and requesting data from a storage node (data module 720 on a client node). Storage management system 718 can also include instructions for providing uncompressed data to a client node (data module 720 on a storage node). Furthermore, storage management system 718 includes instructions for compressing data in the read path from a local client cache (collaborative compression module 722 on a client node). Storage management system 718 can also include instructions for decompressing data in the read path from a local storage device (collaborative compression module 722 on a storage node).

Moreover, storage management system 718 includes instructions for performing CRC check, encryption/decryption, ECC encoding/decoding, and scrambling/descrambling during writing/reading operations, respectively (organization module 724). Storage management system 718 further includes instructions for registering compressed data at one or more master nodes (registration module 726). Storage management system 718 can also include instructions for mapping respective metadata of compressed and uncompressed data (mapping module 728). In addition, storage management system 718 includes instructions for bypassing the decompression operation in the read path from a local storage device during a background read (background read module 730). Storage management system 718 includes instructions for querying the master nodes (query module 732).

Storage management system 718 may further include instructions for sending and receiving messages (communication module 734). Data 736 can include any data that can facilitate the operations of storage management system 718, such as original data 302, compressed data 304, registration data, and mapping 320.

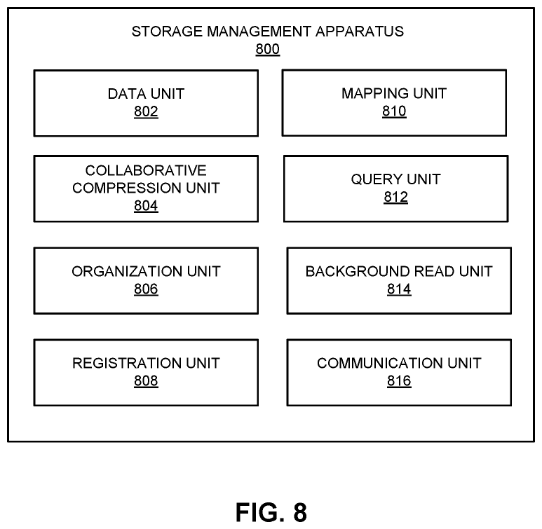

FIG. 8 illustrates an exemplary apparatus that facilitates collaborative compression in a distributed storage system, in accordance with an embodiment of the present application. Storage management apparatus 800 can comprise a plurality of units or apparatuses which may communicate with one another via a wired, wireless, quantum light, or electrical communication channel. Apparatus 800 may be realized using one or more integrated circuits, and may include fewer or more units or apparatuses than those shown in FIG. 8. Further, apparatus 800 may be integrated in a computer system, or realized as a separate device that is capable of communicating with other computer systems and/or devices. Specifically, apparatus 800 can include units 802-816, which perform functions or operations similar to modules 720-734 of computer system 700 of FIG. 7, including: a data unit 802; a collaborative compression unit 804; an organization unit 806; a registration unit 808; a mapping unit 810; a query unit 812; a background read unit 814; and a communication unit 816.

The data structures and code described in this detailed description are typically stored on a computer-readable storage medium, which may be any device or medium that can store code and/or data for use by a computer system. The computer-readable storage medium includes, but is not limited to, volatile memory, non-volatile memory, magnetic and optical storage devices such as disks, magnetic tape, CDs (compact discs), DVDs (digital versatile discs or digital video discs), or other media capable of storing computer-readable media now known or later developed.

The methods and processes described in the detailed description section can be embodied as code and/or data, which can be stored in a computer-readable storage medium as described above. When a computer system reads and executes the code and/or data stored on the computer-readable storage medium, the computer system performs the methods and processes embodied as data structures and code and stored within the computer-readable storage medium.

Furthermore, the methods and processes described above can be included in hardware modules. For example, the hardware modules can include, but are not limited to, application-specific integrated circuit (ASIC) chips, field-programmable gate arrays (FPGAs), and other programmable-logic devices now known or later developed. When the hardware modules are activated, the hardware modules perform the methods and processes included within the hardware modules.

The foregoing embodiments described herein have been presented for purposes of illustration and description only. They are not intended to be exhaustive or to limit the embodiments described herein to the forms disclosed. Accordingly, many modifications and variations will be apparent to practitioners skilled in the art. Additionally, the above disclosure is not intended to limit the embodiments described herein. The scope of the embodiments described herein is defined by the appended claims.

What is claimed is:

1. An apparatus, comprising:
a storage unit configured to store a piece of data;
a control unit configured to determine whether data stored in the storage unit has triggered a storage operation in a distributed storage system;
a compression unit configured to compress the piece of data by encoding the piece of data using fewer bits than the bits of the piece of data; and
a communication unit configured to send the compressed piece of data to a plurality of storage nodes in the distributed storage system for persistent storage.

2. The apparatus of claim 1, wherein the storage operation is triggered in response to one of:
data stored in the storage unit reaching a threshold; and
a timer expiring for the storage unit.

3. The apparatus of claim 1, wherein the control unit is further configured to query for a storage path for the compressed piece of data from a master node of the distributed storage service, wherein the storage path indicates the plurality of storage nodes.

4. The apparatus of claim 3, wherein the control unit is further configured to:
query the master node for a location of the compressed piece of data based on metadata associated with the piece of data; and
determine a storage node from the plurality of storage nodes based on a query response from the master node; and
wherein the communication circuitry is further configured to send a read request to the storage node for the compressed piece of data.

5. The apparatus of claim 4, wherein the communication unit is further configured to receive the piece of data with original bits from the storage node.

6. The apparatus of claim 1, further comprising an interface unit configured to perform a storage read operation on the piece of data, wherein the storage read operation is executed for reading data from the storage unit and transferring data to one or more storage nodes for persistent storage.

7. The apparatus of claim 1, further comprising an organization unit configured to apply a set of organization operations on the piece of data that excludes operations of the compression circuitry prior to storing the piece of data in the storage unit, wherein the set of organization operations includes one or more of: encryption, data validation, error-correction code (ECC) encoding, and data scrambling.

8. An apparatus, comprising:
a non-volatile storage unit configured to store a compressed piece of data;
an interface unit configured to identify a request for the compressed piece of data from a client node of a distributed storage system;
a control unit configured to determine that the request for the compressed piece of data triggers a user read operation;
a decompression unit configured to decompress the compressed piece of data to generate a piece of data, wherein the compressed piece of data includes fewer bits than the bits of the piece of data; and
a communication unit configured to send the piece of data to the client node.

9. The apparatus of claim 8, wherein the communication unit is configured to receive a message comprising a compressed piece of data; and
wherein the control unit is further configured to determine that the compressed piece of data has been compressed.

10. The apparatus of claim 9, further comprising an organization unit configured to apply a set of organization operations on the compressed piece of data that excludes operations of compression circuitry of the apparatus, wherein the set of organization operations includes one or more of: encryption, data validation, error-correction code (ECC) encoding, and data scrambling.

11. The apparatus of claim 8, wherein the control unit is further configured to:
determine that a background read has been initiated for the compressed piece of data;
obtain the compressed piece of data from the storage unit; and
bypass the operations of the decompression circuitry for the compressed piece of data.

12. The apparatus of claim 11, wherein the control unit is further configured to perform an operation associated with the background read in conjunction with a plurality of storage nodes of the distributed storage system, wherein a respective storage node of the plurality of storage nodes stores a copy of the compressed piece of data.

13. The apparatus of claim 12, wherein the control unit is further configured to query a master node of the distributed storage system to determine the plurality of storage nodes.

14. The apparatus of claim 8, wherein the storage unit comprises a plurality of non-volatile memory cells facilitating persistent storage.

15. A computer system, comprising:
a processor; and
a memory coupled to the processor and storing instructions, which when executed by the processor cause the processor to perform a method, the method comprising:
receiving a first piece of metadata associated with a piece of data from a client node of a distributed storage system;
receiving a second piece of metadata associated with a compressed piece of data from the client node, wherein the compressed piece of data is generated by compressing the piece of data and includes fewer bits than the bits of the piece of data;
registering the first piece of metadata for the distributed storage system; and
generating a mapping between the first and second pieces of metadata.

16. The computer system of claim 15, wherein the method further comprises:
generating a storage path indicating a plurality of storage nodes of the distributed storage system for the compressed piece of data; and
sending the storage path to the client node.

17. The computer system of claim 16, wherein the method further comprises storing the storage path in association with the second piece of metadata.

18. The computer system of claim 16, wherein the method further comprises:
receiving a query for information based on the first piece of metadata;
looking up in the mapping to obtain the second piece of metadata; and
retrieving the storage path based on the second piece of metadata.

19. The computer system of claim 16, wherein the method further comprises:
selecting a storage node from the plurality of storage nodes for retrieving the piece of data; and
sending, to the client node, a notification indicating the selected storage node.

20. The computer system of claim 15, wherein the method further comprises sending an instruction message to a storage node indicating a location for storing the compressed piece of data.
